(19) United States
(12) Patent Application Publication
(10) Pub. No.: US 2024/0170294 A1
(43) Pub. Date: May 23, 2024

(54) Silicon Etching Solution, Method for Treating Substrate, and Method for Manufacturing Silicon Device

(71) Applicant: Tokuyama Corporation, Yamaguchi (JP)

(72) Inventors: Tatsuya Hitomi, Yamaguchi (JP); Yoshiki Seike, Yamaguchi (JP); Kohshiro Okimura, Yamaguchi (JP); Kohsuke Noro, Yamaguchi (JP)

(73) Assignee: Tokuyama Corporation, Yamaguchi (JP)

(21) Appl. No.: 18/515,415

(22) Filed: Nov. 21, 2023

(30) Foreign Application Priority Data
Nov. 22, 2022 (JP) 2022-186930
Nov. 17, 2023 (JP) 2023-195604

(51) Int. Cl. H01L 21/306

(52) U.S. Cl. CPC H01L 21/30608

(57) ABSTRACT

In etching of a single crystal silicon substrate having a Si crystal plane ((100) plane, (110) plane, and (111) plane) as a main plane, an etching rate on the (110) plane cannot be sufficiently reduced, and there is room for improvement in an etching rate ratio between the (110) plane and the (111) plane. An object of the present invention is to provide a silicon etching solution having excellent crystal plane isotropy in silicon etching and having a high etching selectivity ratio of silicon to a silicon oxide film.

The problem is solved by a silicon etching solution containing: an acid group-containing compound having at least one acid group selected from the group consisting of a carboxy group, a sulfonic acid group, a phosphoric acid group, and a phosphonic acid group, and having pKa of 3.5 or more and 13 or less; a quaternary ammonium hydroxide; an oxidizing agent; and water.

This US patent application claims priority to Japanese patent document 2022-186930 filed on Nov. 22, 2022 and Japanese patent document 2023-195604 filed on Nov. 17, 2023 in the Japanese Patent Office. Both application documents are hereby incorporated by reference in their entireties.

### BACKGROUND OF THE INVENTION

### Field of the Invention

The present invention relates to a silicon etching solution used in surface processing and an etching step in manufacturing various silicon devices. The present invention also relates to a method for treating a substrate using the etching solution. Examples of the substrate include a semiconductor wafer or a silicon substrate. The present invention further relates to a method for manufacturing a silicon device using the etching solution.

### Description of the Related Art

In recent years, silicon etching has been applied to producing a semiconductor memory such as a 3D NAND and producing a logic semiconductor having a structure called a fin field-effect transistor (Fin-FET) or gate all around (GAA). In a silicon etching technique used here, due to densification of a device and complication of a structure, a stricter requirement is imposed on smoothness of a wafer surface after etching, an etching accuracy, and an etching selectivity to other materials.

On the other hand, various silicon etching solutions are proposed and are actually used. Among them, it is widely known that an etching agent (alkaline etching solution) which is an alkaline aqueous solution usually exhibits crystal plane anisotropy in etching with respect to crystalline silicon.

The alkaline etching solution is used for bulk micromachining or the like by utilizing the crystal plane anisotropy in etching. However, when the alkaline etching solution is applied to producing the semiconductor memory such as a 3D NAND and producing the logic semiconductor having a three-dimensional structure such as a Fin-FET or GAA, there is a problem that a shape of a surface after etching is not parallel to an etching initiation plane due to the crystal plane anisotropy in etching, or a pyramid-shaped hillock constituted by a (111) plane is generated to deteriorate the smoothness. That is, in an etching treatment in producing the semiconductor memory such as a 3D NAND and producing the logic semiconductor having a three-dimensional structure such as a Fin-FET or GAA, the crystal plane isotropy in etching may be required.

An example of an etching solution exhibiting the crystal plane isotropy in etching includes a hydrofluoric acid-nitric acid aqueous solution (acid-based etching solution). However, since the hydrofluoric acid-nitric acid aqueous solution etches a silicon oxide film, a selectivity ratio of etching silicon with respect to etching the silicon oxide film is low. In the etching treatment in producing the semiconductor memory such as a 3D NAND and producing a complicated structure such as the logic semiconductor having a three-dimensional structure such as a Fin-FET or GAA, high etching selectivity of silicon to the silicon oxide film may be required, and in such a case, the hydrofluoric acid-nitric acid aqueous solution (acid-based etching solution) cannot be applied.

Therefore, there is a demand for a silicon etching solution which exhibits crystal plane isotropy in silicon etching and a high etching selectivity ratio of silicon (hereinafter, silicon is also referred to as Si) to the silicon oxide film. In general, the alkaline etching solution has a high etching selectivity ratio of silicon to the silicon oxide film. Here, the etching selectivity ratio of silicon to the silicon oxide film represents a value obtained by dividing an etching rate of silicon by an etching rate of the silicon oxide film.

As a method for improving the crystal plane isotropy in etching in silicon etching using an alkaline etching solution, Japanese Patent Laid-Open No. 2019-153721 discloses an etching solution containing an organic alkali, an oxidizing agent, and water. Japanese Patent Laid-Open No. 2002-231666 discloses a polishing composition containing a quaternary ammonium salt, a carboxylic acid, hydrogen peroxide, water, and an abrasive. Japanese Patent Laid-Open No. 2014-103349 discloses a semiconductor cleaning composition containing a quaternary ammonium compound, a carboxylic acid, hydrogen peroxide, and a surfactant. Japanese Patent Laid-Open No. 2021-150515 discloses a polishing composition containing an abrasive grain, an inorganic salt, a polishing accelerator containing an acid group, and an acid or alkali as a pH adjuster.

The present inventors have performed etching of a single crystal silicon substrate having each crystal plane ((100) plane, (110) plane, and (111) plane) as a main plane using the etching solution in Japanese Patent Laid-Open No. 2019-153721, and have found that an etching rate on the (100) plane can be reduced to a rate equivalent to that on the (111) plane by adjusting a concentration of the oxidizing agent disclosed in Japanese Patent Laid-Open No. 2019-153721, but an etching rate on the (110) plane cannot be sufficiently reduced, and there is room for improvement in an etching rate ratio between the (110) plane and the (111) plane. In addition, the polishing composition or the cleaning composition described in Japanese Patent Laid-Open No. 2002-231666, Japanese Patent Laid-Open No. 2014-103349, and Japanese Patent Laid-Open No. 2021-150515 is not intended to be applied to silicon etching.

### SUMMARY OF THE INVENTION

Therefore, an object of the present invention is to provide a silicon etching solution having excellent crystal plane isotropy in silicon etching and having a high etching selectivity ratio of silicon to a silicon oxide film.

The present inventors have conducted intensive studies in view of the above problems. As a result, it has been found that a surface of a silicon substrate is hydrophilized in an etching solution containing an oxidizing agent, an effect of reducing etching on all crystal planes is not exerted by adding a compound that is adsorbed by hydrophobic interaction, and the crystal plane isotropy in etching is not improved. Therefore, the present inventors have conducted further studies focusing on a compound that is adsorbed to an oxide, and have found that by adding an acid group-containing compound having an acid group and having at least one pKa (acid dissociation constant) of 3.5 or more and 13 or less to the etching solution containing the oxidizing agent in a specific concentration range, only an etching rate on the (110) plane can be selectively reduced, and the crystal plane isotropy in etching is improved, thereby completing the present invention.

That is, the present invention includes the following gist.

(1) A silicon etching solution containing:
a quaternary ammonium hydroxide;
an oxidizing agent;
water; and
an acid group-containing compound having at least one acid group selected from the group consisting of a carboxy group, a sulfonic acid group, a phosphoric acid group, and a phosphonic acid group, and having at least one pKa of 3.5 or more and 13 or less.

(2) The silicon etching solution according to (1), in which the acid group-containing compound has only one acid group.

(3) The silicon etching solution according to (2), in which the acid group-containing compound has a carboxy group and has an HLB value of 23.0 or more and 25.5 or less.

(4) The silicon etching solution according to (3), in which the content of the acid group-containing compound is 0.001 mol/L or more and 0.1 mol/L or less.

(5) The silicon etching solution according to (1), in which the acid group-containing compound is one or more compounds selected from the group consisting of propanoic acid, butanoic acid, pentanoic acid, hexanoic acid, heptanoic acid, octanoic acid, isopropanoic acid, isobutanoic acid, isopentanoic acid, isohexanoic acid, isoheptanoic acid, isooctanoic acid, 2-cyclobutylacetic acid, cyclopentanecarboxylic acid, cyclohexanecarboxylic acid, succinic acid, glutaric acid, adipic acid, pimelic acid, suberic acid, azelaic acid, sebacic acid, tridecanedioic acid, methylsuccinic acid, tetramethylsuccinic acid, benzoic acid, terephthalic acid, gluconic acid, phosphoric acid, ethylphosphonic acid, propylphosphonic acid, butylphosphonic acid, pentylphosphonic acid, heptylphosphonic acid, octylphosphonic acid, isopropylphosphonic acid, isobutylphosphonic acid, isopentylphosphonic acid, isoheptylphosphonic acid, isooctylphosphonic acid, and salts thereof.

(6) The silicon etching solution according to any one of (1) to (5), in which the oxidizing agent is one or more selected from the group consisting of hydrogen peroxide, meta-chloroperoxybenzoic acid, and an N-oxyl compound.

(7) A method for treating a substrate, including: a step of bringing the silicon etching solution according to any one of (1) to (5) into contact with a substrate having a Si plane to etch the Si plane.

(8) A method for treating a substrate, including: a step of bringing the silicon etching solution according to (6) into contact with a substrate having a Si plane to etch the Si plane.

(9) A method for manufacturing a silicon device, including: the method for treating a substrate according to (7) during manufacturing a silicon device.

(10) A method for manufacturing a silicon device, including: the method for treating a substrate according to (8) during manufacturing a silicon device.

By using the silicon etching solution of the present invention, it is possible to perform an etching treatment on silicon with low crystal plane anisotropy (high crystal plane isotropy) and a high etching selectivity ratio of silicon to a silicon oxide film.

### DETAILED DESCRIPTION OF THE PREFERRED EMBODIMENTS

Hereinafter, an embodiment of the present invention will be described in detail, but the present invention is not limited to these contents unless the gist thereof is exceeded. In addition, the present invention can be freely modified and implemented within a scope without departing from the gist thereof.

In the present specification, a numerical range expressed using “to” means a range including numerical values described before and after “to” as a lower limit value and an upper limit value, and “A to B” means A or more and B or less.

1. Etching Solution

A silicon etching solution of the present invention (hereinafter referred to as an “etching solution of the present invention”) is used for etching silicon (crystalline silicon, polysilicon, and amorphous silicon) during manufacturing of a semiconductor chip or the like. Etching of silicon can be performed under an acid condition or under an alkaline condition, but the etching solution of the present invention is an alkaline aqueous solution and is used for etching under the alkaline condition.

In the above manufacturing of a semiconductor chip, when a treatment solution such as an etching solution contains a metal, the metal often has an adverse influence on an object to be treated (not limited to a silicon plane to be etched).

Therefore, it is necessary that the etching solution of the present invention does not contain a metal. More specifically, it is essential that the etching solution does not contain the metal at least at a concentration exceeding an impurity level. Preferably, each of Ag, Al, Ba, Ca, Cd, Co, Cr, Cu, Fe, K, Li, Mg, Mn, Na, Ni, Pb, and Zn has a content of 1 ppmw or less, and more preferably, each of the above metals has a content of 1 ppbw or less. Each of the metals listed herein is a metal that is expected to influence quality in a chemical solution used for manufacturing a semiconductor.

Further, among the above metals, any one metal selected from iron, copper, manganese, chromium, and zinc is preferably 0.01 ppt or more and 1 ppb or less, more preferably 0.01 ppt or more and 0.5 ppb or less, even more preferably 0.01 ppt or more and 0.2 ppb or less, and most preferably 0.01 ppt or more and 0.1 ppb or less on a weight basis. The etching solution of the present invention may contain an ionic metal or a nonionic metal (particulate metal) as a metal. A total concentration of the ionic metal and the nonionic metal is preferably in the above range.

Since the etching solution of the present invention is the alkaline aqueous solution and is used for etching under the alkaline condition as described above, the etching solution contains an alkaline source as an essential component. Under the alkaline condition, since silicon can be etched without containing a component that can contribute to etching of a silicon oxide film such as fluorine ions, silicon can be etched at a high selectivity ratio with respect to the silicon oxide film.

The alkaline source in the etching solution of the present invention is a quaternary ammonium hydroxide.

Specific examples of the quaternary ammonium hydroxide include tetramethylammonium hydroxide, ethyltrimethylammonium hydroxide, propyltrimethylammonium hydroxide, butyltrimethylammonium hydroxide, tetraethylammonium hydroxide, tetrapropylammonium hydroxide, tetrabutylammonium hydroxide, trimethyl-2-hydroxyethylammonium hydroxide, dimethylbis(2-hydroxyethyl)ammonium hydroxide or methyltris(2-hydroxyethyl)ammonium hydroxide, phenyltrimethylammonium hydroxide, and benzyltrimethylammonium hydroxide.

The quaternary ammonium hydroxide has good stability against a peroxide. From a viewpoint of stability against a peroxide, among the above, a quaternary ammonium hydroxide having no hydroxy group in a cation is more preferable. Specific examples of the cation contained in the quaternary ammonium hydroxide include a tetramethylammonium hydroxide ion, an ethyltrimethylammonium hydroxide ion, a propyltrimethylammonium hydroxide ion, a butyltrimethylammonium hydroxide ion, a tetraethylammonium hydroxide ion, a tetrapropylammonium hydroxide ion, and a tetrabutylammonium hydroxide ion. Among them, from a viewpoint of exhibiting a high etching rate, a tetramethylammonium hydroxide ion, an ethyltrimethylammonium hydroxide ion, a propyltrimethylammonium hydroxide ion, a butyltrimethylammonium hydroxide ion, and a tetraethylammonium hydroxide ion are particularly preferable.

In the etching solution of the present invention, regarding the quaternary ammonium hydroxide, one type may be used alone, or a plurality of different types thereof may be mixed and used.

As the alkaline source, in addition to the quaternary ammonium hydroxide, various amines may be used in combination. As the various amines, primary amines, secondary amines, or tertiary amines can be used. As the primary amines or the secondary amines, for example, one or more selected from the group consisting of ethylenediamine, 1,3-diaminopropane, 1,4-diaminobutane, 1,5-diaminopentane, 1,6-diaminohexane, 1,7-diaminoheptane, 1,8-diaminooctane, 1,1,3,3-tetramethylguanidine, diethylenetriamine, dipropylenetriamine, bis(hexamethylene)triamine, N,N,N-trimethyldiethylenetriamine, N,N-bis(3-aminopropyl)ethylenediamine, 2-(2-aminoethoxy)ethanol, 2-amino-2-methyl-1-propanol, 4-amino-1-butanol, 5-amino-1-pentanol, 6-amino-1-hexanol, N-(2-aminoethyl)propanolamine, N-(2-hydroxypropyl)ethylenediamine, azetidine, pyrrolidine, piperidine, hexamethyleneimine, pentamethyleneimine, and octamethyleneimine can be used.

Specifically, examples of the tertiary amines include one or more selected from the group consisting of 2-(dimethylamino)ethanol, 3-(dimethylamino)-1-propanol, 4-dimethylamino-1-butanol, 2-(diethylamino)ethanol, triethylamine, methylpyrrolidine, methylpiperidine, 1,8-diazabicyclo[5.4.0]undec-7-ene, and 1,5-diazabicyclo[4.3.0]non-5-ene. More preferable examples thereof include one or more selected from the group consisting of ethylenediamine, 1,3-diaminopropane, 1,4-diaminobutane, 1,5-diaminopentane, 1,6-diaminohexane, 1,1,3,3-tetramethylguanidine, diethylenetriamine, dipropylenetriamine, bis(hexamethylene)triamine, 2-(2-aminoethoxy)ethanol, 2-amino-2-methyl-1-propanol, 4-amino-1-butanol, 5-amino-1-pentanol, 6-amino-1-hexanol, N-(2-aminoethyl)propanolamine, pyrrolidine, piperidine, hexamethyleneimine, and pentamethyleneimine. Even more preferable examples thereof include one or more selected from the group consisting of ethylenediamine, 1,3-diaminopropane, 1,4-diaminobutane, 1,5-diaminopentane, 1,6-diaminohexane, 1,1,3,3-tetramethylguanidine, diethylenetriamine, dipropylenetriamine, bis(hexamethylene)triamine, 2-(2-aminoethoxy)ethanol, 2-amino-2-methyl-1-propanol, pyrrolidine, and piperidine.

In etching of single crystal silicon, among a Si (100) plane, a Si (110) plane, and a Si (111) plane, etching of the Si (110) plane is most likely to be limited by an alkali supply rate. Therefore, as an alkali concentration is lower (accordingly, alkalinity is lower), isotropy in etching tends to be improved. On the other hand, when the alkali concentration is too low, the etching rate becomes slow, productivity deteriorates, and a variation of the etching rate with respect to a concentration of the peroxide becomes large, so that a process window becomes narrow. Therefore, the etching solution of the present invention has a pH of 10.0 or more and 14.0 or less, more preferably 11.0 or more and 14.0 or less, and particularly preferably 11.5 or more and 13.5 or less. The pH refers to a value measured at 25° C. by a glass electrode method.

The most important feature of the etching solution of the present invention is that a solution containing a quaternary ammonium hydroxide, an oxidizing agent, and water contains a compound (acid group-containing compound) having at least one acid group selected from the group consisting of a carboxy group, a sulfonic acid group, a phosphoric acid group, and a phosphonic acid group and having at least one pKa of 3.5 or more and 13 or less. Here, the “acid group” refers to a “functional group that releases a hydrogen atom by acid dissociation” and a “state of an anion after acid dissociation of an acid-dissociable functional group”. That is, in the etching solution of the present invention, the acid group-containing compound may be contained in a non-dissociated state or in an acid-dissociated state. When an aqueous solution contains the acid group-containing compound in addition to the quaternary ammonium hydroxide and the oxidizing agent, an etching rate on the (110) plane is selectively reduced and crystal plane anisotropy in silicon etching can be reduced as compared with a case where the acid group-containing compound is not contained.

On the other hand, when all pKa's of the acid group-containing compound are less than 3.5, an effect of reducing the crystal plane anisotropy in silicon etching is reduced.

A reason for this is not clear, but is presumed as follows. That is, it is known that a surface charge of a silicon surface is generally negative in an alkaline solution, and it is considered that the anion is less likely to approach the silicon surface by static repulsion. However, it is presumed that in a case of the acid group-containing compound, adsorption of a small amount of the acid group in a non-dissociated state to a hydroxy group on the silicon surface contributes to reduction of etching of silicon. Although a dangling bond density and a hydroxy group density on the silicon surface do not always coincide with a difference in degrees of oxidation between crystal planes, a relation between the crystal planes in terms of the dangling bond density on the silicon surface is as follows: Si (111) plane<Si (110) plane<Si (100) plane. It is considered that in the Si (100) plane, two dangling bonds are positioned so as to face each other, and when a compound having an acid group is adsorbed to one dangling bond, the compound is less likely to be adsorbed to the other dangling bond due to steric hindrance. Therefore, it is presumed that adsorption of the acid group-containing compound to the hydroxy group is most likely to occur on the Si (110) plane, and etching of the Si (110) plane is selectively reduced.

The acid group-containing compound in the etching solution of the present invention preferably has a content of 0.001 mol/L or more and 0.1 mol/L or less, more preferably 0.005 mol/L or more and 0.07 mol/L or less, and even more preferably 0.005 mol/L or more and 0.03 mol/L or less. A concentration of the compound can be determined by ion chromatography.

Examples of the acid group-containing compound include propanoic acid, butanoic acid, pentanoic acid, hexanoic acid, heptanoic acid, octanoic acid, isopropanoic acid, isobutanoic acid, isopentanoic acid, isohexanoic acid, isoheptanoic acid, isooctanoic acid, 2-cyclobutylacetic acid, cyclopentanecarboxylic acid, cyclohexanecarboxylic acid, succinic acid, glutaric acid, adipic acid, pimelic acid, suberic acid, azelaic acid, sebacic acid, tridecanedioic acid, methylsuccinic acid, tetramethylsuccinic acid, benzoic acid, phthalic acid, terephthalic acid, gluconic acid, phosphoric acid, ethylphosphonic acid, propylphosphonic acid, butylphosphonic acid, pentylphosphonic acid, heptylphosphonic acid, octylphosphonic acid, isopropylphosphonic acid, isobutylphosphonic acid, isopentylphosphonic acid, isoheptylphosphonic acid, isooctylphosphonic acid, and salts thereof. A compound having only one acid group is more preferable from a viewpoint of a high effect in reducing the etching rate on the silicon (110) plane, and specific examples thereof include propanoic acid, butanoic acid, pentanoic acid, hexanoic acid, heptanoic acid, octanoic acid, isopropanoic acid, isobutanoic acid, isopentanoic acid, isohexanoic acid, isoheptanoic acid, isooctanoic acid, 2-cyclobutylacetic acid, cyclopentanecarboxylic acid, cyclohexanecarboxylic acid, benzoic acid, gluconic acid, phosphoric acid, ethylphosphonic acid, propylphosphonic acid, butylphosphonic acid, pentylphosphonic acid, heptylphosphonic acid, octylphosphonic acid, isopropylphosphonic acid, isobutylphosphonic acid, isopentylphosphonic acid, isoheptylphosphonic acid, isooctylphosphonic acid, and salts thereof. From a viewpoint of stability against the peroxide, among the above, an acid group-containing compound having no hydroxy group in a side chain is more preferable.

A type of the acid group contained in the acid group-containing compound may be any functional group among a carboxy group, a sulfonic acid group, a phosphoric acid group, or a phosphonic acid group as long as at least one pKa among the pKa's of the acid group-containing compound is 3.5 or more and 13 or less, and may contain a plurality of such functional groups. When the pKa of the acid group-containing compound is more than 13, solubility may decrease even in the alkaline aqueous solution, so that the pKa of the acid group-containing compound is preferably 3.5 or more and 13 or less, more preferably 3.5 or more and 11 or less, even more preferably 3.5 or more and 10 or less, and particularly preferably 3.5 or more and 8 or less. In a case of a compound in which the acid group is a carboxy group, stability in a state of being bonded to the hydroxy group is lower than that of a phosphoric acid or an alkylphosphonic acid, so that it is preferable that the compound has a structure in which side chains can be stabilized by interaction in the bonded state. Specifically, the acid group-containing compound preferably has an HLB value of 25.5 or less. Examples of such an acid group-containing compound include propanoic acid, butanoic acid, pentanoic acid, hexanoic acid, heptanoic acid, octanoic acid, nonanoic acid, decanoic acid, undecanoic acid, dodecanoic acid, isobutanoic acid, isopentanoic acid, isohexanoic acid, isoheptanoic acid, isooctanoic acid, isononanoic acid, isodecanoic acid, 2-cyclobutylacetic acid, cyclopentanecarboxylic acid, cyclohexanecarboxylic acid, benzoic acid, and salts thereof.

The above HLB value is a value indicating a balance between hydrophilicity and hydrophobicity of a compound, and is a value calculated by a Davies method to be described later. The higher the HLB value, the higher the hydrophilicity of the compound, and the lower the HLB value, the higher the hydrophobicity. A compound having an HLB value of less than 23.0 may form a micelle, and when it is attempted to remove a particle in a chemical solution by filtering, the compound present as the micelle is removed, and a concentration of the compound in the chemical solution may change. On the other hand, when the HLB value of the compound is more than 25.5, the stability of the compound in the chemical solution is increased, or hydrophobic interaction between the side chains in an adsorbed state is small and the stability of the adsorption is lowered, so that an effect of reducing etching is hardly obtained. In the case of the compound in which the acid group is a carboxy group, when the HLB value of the compound is in a specific range, the effect of reducing the crystal plane anisotropy in silicon etching can be enhanced. It is preferable that the above HLB value is 23.0 to 25.5 because the effect of reducing the crystal plane anisotropy can be sufficiently obtained. Specific examples of such an acid group-containing compound include propanoic acid, butanoic acid, pentanoic acid, hexanoic acid, heptanoic acid, isobutanoic acid, isopentanoic acid, isohexanoic acid, isoheptanoic acid, 2-cyclobutylacetic acid, cyclopentanecarboxylic acid, cyclohexanecarboxylic acid, benzoic acid, and salts thereof. The above HLB value is more preferably 23.0 to 25.0, and specific examples of the acid group-containing compound include butanoic acid, pentanoic acid, hexanoic acid, heptanoic acid, isobutanoic acid, isopentanoic acid, isohexanoic acid, isoheptanoic acid, 2-cyclobutylacetic acid, cyclopentanecarboxylic acid, cyclohexanecarboxylic acid, benzoic acid, and salts thereof. It is particularly preferable that the above HLB value is 23.0 to 24.0 because the effect of reducing the crystal plane anisotropy can be sufficiently obtained. Specific examples thereof include hexanoic acid, heptanoic acid, isohexanoic acid, isoheptanoic acid, 2-cyclobutylacetic acid, cyclopentanecarboxylic acid, cyclohexanecarboxylic acid, benzoic acid, and salts thereof. In the etching solution of the present invention, the acid group-containing compound may be dissociated and present in a form of ions. That is, the acid group-containing compound includes both a compound in which the acid group (a carboxy group, a sulfonic acid group, a phosphoric acid group, or a phosphonic acid group) of the compound is in a non-dissociated form and a compound in which the acid group is in an anion form. When the acid group is present in the anion form, a counter cation is preferably a non-metal cation. Specifically, various ammonium cations are more preferable, and among them, a quaternary ammonium cation is even more preferable. More specific examples thereof include a tetramethylammonium cation, an ethyltrimethylammonium cation, a propyltrimethylammonium cation, a butyltrimethylammonium cation, a tetraethylammonium cation, a tetrapropylammonium cation, a tetrabutylammonium cation, a phenyltrimethylammonium cation, and a benzyltrimethylammonium cation. It is particularly preferable in terms of etching isotropy that a cation having a large number of carbon atoms is contained. Specific examples thereof include a tetraethylammonium cation, a tetrapropylammonium cation, a tetrabutylammonium cation, a phenyltrimethylammonium cation, and a benzyltrimethylammonium cation. On the other hand, it is particularly preferable in terms of a silicon etching rate that a cation having a small number of carbon atoms is contained. Specific examples thereof include a tetramethylammonium cation, an ethyltrimethylammonium cation, and a propyltrimethylammonium cation.

The oxidizing agent contained in the etching solution of the present invention is not particularly limited, and examples thereof include an N-oxyl compound, hydrogen peroxide, and meta-chloroperoxybenzoic acid. Specific examples of the N-oxyl compound include nor-AZADO and 4-hydroxy-2,2,6,6-tetramethylpiperidine-1-oxyl (TEMPOL).

The oxidizing agent in the etching solution of the present invention preferably has a content of 0.01 mol/L or more and 0.30 mol/L or less, more preferably 0.03 mol/L or more and 0.20 mol/L or less, and particularly preferably 0.05 mol/L or more and 0.10 mol/L or less. A concentration of the compound can be determined by an iodometric method.

The etching solution of the present invention is an alkaline aqueous solution, and water is an essential component as a remainder of a composition of the etching solution. If there is no water, etching does not proceed. Although a proportion of water depends on types and amounts of other components, in general, the proportion of water is preferably 30% by mass or more and less than 100% by mass, more preferably 50% by mass or more and less than 100% by mass, even more preferably 60% by mass or more and less than 100% by mass, and particularly preferably 75% by mass or more and less than 100% by mass. In addition, an upper limit is not particularly limited as long as the other components can be contained in a necessary amount, and the upper limit is usually 99.5% by mass, and 99% by mass is sufficient.

The silicon etching solution of the present invention may further contain a known component contained in a silicon etching solution containing an alkaline aqueous solution. However, of course, it is preferable that a compound having high reactivity with the oxidizing agent is not contained.

Examples of the components which may be contained in the silicon etching solution include: one or more water-soluble or water-miscible organic solvents selected from the group consisting of ethers having a plurality of ether bonds, such as diethylene glycol dimethyl ether, diethylene glycol methyl ethyl ether, and diethylene glycol diethyl ether; one or more quaternary ammonium halogen salts selected from the group consisting of tetrapropylammonium chloride, tetrapropylammonium bromide, tetrabutylammonium chloride, tetrabutylammonium bromide, dodecyltrimethylammonium bromide, and decyltrimethylammonium bromide; or quaternary ammonium BF₄ salts.

On the other hand, when silicon is etched in the manufacturing of the semiconductor chip, a silicon dioxide portion (surface) and a silicon nitride portion (surface) are often non-etching target objects. Therefore, it is preferable that the etching solution of the present invention does not contain a component that promotes etching of silicon dioxide (SiO₂) or silicon nitride (SiN). A typical example of such a component is a fluoride ion.

The silicon etching solution of the present invention is preferably a homogeneous solution in which all components to be blended are dissolved. Further, in the sense of preventing contamination during etching, the number of particles of 200 nm or more is preferably 100 particles/mL or less, and more preferably 50 particles/mL or less. Further, the silicon etching solution of the present invention may contain gases such as hydrogen and oxygen for convenience in producing the silicon etching solution.

2. Method for Producing Etching Solution

A method for producing the etching solution of the present invention is not particularly limited, and includes, for example, mixing the quaternary ammonium hydroxide, the oxidizing agent, and the acid group-containing compound with water to a predetermined concentration and dissolving them uniformly.

As described above, since the etching solution of the present invention does not contain a metal at a concentration more than an impurity level, it is not preferable to use a metal hydroxide such as NaOH or KOH in combination as the alkali compound.

As the quaternary ammonium hydroxide, one containing as few metal impurities and insoluble impurities as possible is preferably used, and a commercially available product can be purified and used by recrystallization, column purification, ion exchange purification, filtration, or the like as necessary. Depending on a type of the quaternary ammonium hydroxide, an extremely high purity type is manufactured and sold for use in semiconductor manufacturing, and such quaternary ammonium hydroxide is preferably used. In general, a high-purity quaternary ammonium hydroxide for use in semiconductor manufacturing is sold as a solution such as an aqueous solution. In manufacturing the silicon etching solution of the present invention, this solution may be mixed with water or other blending components as it is.

An amount of the quaternary ammonium hydroxide necessary for setting the pH of the etching solution to 10.0 or more is generally 0.1 mmol/L or more, although the amount depends on types and blending amounts of the other components.

As described above, in the etching solution of the present invention, the acid group-containing compound is a compound having an acid group (a carboxy group, a sulfonic acid group, a phosphoric acid group, or a phosphonic acid group), and may be present in the form of ions. Therefore, as a compound having at least one acid group (a carboxy group, a sulfonic acid group, a phosphoric acid group, or a phosphonic acid group) and having at least one pKa of 3.5 or more and 13 or less, a salt thereof may be used. The salt is preferably a non-metal salt. Specifically, various ammonium salts are more preferable, and among them, a quaternary ammonium salt is particularly preferable. More specific examples thereof include a tetramethylammonium salt, an ethyltrimethylammonium salt, a tetraethylammonium salt, a tetrapropylammonium salt, a tetrabutylammonium salt, a phenyltrimethylammonium salt, and a benzyltrimethylammonium salt.

It is preferable to use high-purity water containing a small amount of impurities. An amount of impurities can be evaluated by electrical resistivity, and specifically, the electrical resistivity of water is preferably 0.1 MΩ·cm or more, more preferably 15 MΩ·cm or more, and particularly preferably 18 MΩ·cm or more. Such water containing a small amount of impurities can be easily manufactured and obtained as ultrapure water for manufacturing a semiconductor. Further, in a case of ultrapure water, impurities that do not influence (have little contribution to) the electrical resistivity are remarkably decreased, and suitability thereof is high.

As described above, various compounds known as components of a chemical solution for manufacturing a semiconductor may be blended as necessary, but a compound having high reactivity with an oxidizing agent is preferably not blended.

The etching solution of the present invention may contain a quaternary ammonium halogen salt such as tetrapropylammonium chloride, tetrapropylammonium bromide, tetrabutylammonium chloride, tetrabutylammonium bromide, dodecyltrimethylammonium bromide, and decyltrimethylammonium bromide.

In manufacturing the etching solution of the present invention, it is also preferable to mix and dissolve each component, and then pass the mixture through a filter of several nm to several tens of nm to remove a particle. If necessary, the filter passing treatment may be performed a plurality of times.

Further, known treatment such as reducing dissolved oxygen by bubbling with an inert gas such as a high-purity nitrogen gas, and various other known treatments can be performed to obtain a necessary physical property in manufacturing the chemical solution for manufacturing a semiconductor.

For mixing and dissolving (and storing), it is preferable to use a container or an apparatus formed or coated with a known material as an inner wall of the chemical solution for manufacturing a semiconductor, specifically, a material in which a contaminant is hardly eluted into the etching solution, such as polytetrafluoroethylene or high-purity polypropylene. It is also preferable to clean the container and the apparatus in advance.

3. Method for Manufacturing Semiconductor Device

A method for manufacturing a semiconductor device of the present invention includes a step of bringing the above silicon etching solution into contact with silicon.

The etching solution of the present invention is preferably used as an etching solution in manufacturing a semiconductor device such as a silicon device including a step of etching at least one selected from the group consisting of a single crystal silicon wafer, a single crystal silicon film, a polysilicon film, and an amorphous silicon film. The single crystal silicon film includes a film formed by epitaxial growth.

As the method for manufacturing a semiconductor device according to the present invention, a known method for manufacturing a semiconductor device can be used, except for a step of bringing the silicon etching solution of the present invention into contact with a silicon substrate. For example, the method may include known steps used in a method for manufacturing a semiconductor, such as one or more steps selected from a wafer production step, an oxide film forming step, a transistor forming step, a wiring forming step, and a CMP step. Further, it is preferable to include a step of bringing the silicon etching solution of the present invention into contact with a silicon oxide film or a silicon nitride film.

A method of bringing the silicon etching solution of the present invention into contact with the silicon substrate is not particularly limited as long as the silicon etching solution and the silicon substrate are in contact with each other, and examples thereof include a method including a substrate holding step of holding the silicon substrate in a horizontal posture and a treatment solution supplying step of supplying the etching solution of the present invention to a main surface of the substrate while rotating the substrate around a vertical rotation axis passing through a central portion of the substrate, or a method including a substrate holding step of holding a plurality of substrates in an upright posture and a step of immersing the substrate in the etching solution of the present invention stored in a treatment tank in an upright posture.

When the step of bringing the silicon etching solution of the present invention into contact with a silicon oxide film and/or a silicon nitride film is included, the step of bringing the silicon etching solution of the present invention into contact with silicon and the step of bringing the silicon etching solution of the present invention into contact with a silicon oxide film and/or a silicon nitride film may be separate steps, but from a viewpoint of manufacturing efficiency, it is preferable to bring the silicon etching solution into contact with an object containing silicon and a silicon oxide film and/or a silicon nitride film in the same step. The contact in the same step means that a silicon etching solution is simultaneously brought into contact with an object containing silicon and a silicon oxide film and/or a silicon nitride film. For example, by bringing the silicon etching solution into contact with a device structure using silicon as a gate layer or a channel layer and using a silicon oxide film and/or a silicon nitride film as an insulating film, only silicon can be selectively removed from the device structure.

4. Method for Treating Silicon Wafer or Substrate Having Silicon Film

A method for treating a substrate according to the present invention is a method for treating a silicon wafer in which the silicon etching solution of the present invention is brought into contact with a surface of the silicon wafer or a method for treating a substrate having a silicon film in which the silicon etching solution of the present invention is brought into contact with a surface of the substrate having a silicon film. Hereinafter, the method for treating a substrate according to the present invention will be described.

Examples of the method for treating a silicon wafer in which the silicon etching solution of the present invention is brought into contact with the surface of the silicon wafer include a method including a step of etching a single crystal silicon film by supplying the silicon etching solution of the present invention when a silicon wafer, particularly various silicon composite semiconductor devices including a silicon oxide film and/or a silicon nitride film is etched.

Examples of the method for treating a substrate having a silicon film in which the silicon etching solution of the present invention is brought into contact with the surface of the substrate having a silicon film include a method including a substrate holding step of holding the substrate having a silicon film in a horizontal posture and a treatment solution supplying step of supplying the etching solution of the present invention to a main surface of the substrate while rotating the substrate around a vertical rotation axis passing through a central portion of the substrate.

Examples of another method for treating a substrate having a silicon film include a method including a substrate holding step of holding a plurality of substrates in an upright posture, and a step of immersing the substrates in the etching solution of the present invention stored in a treatment tank in an upright posture.

5. Etching Treatment

The silicon etching solution of the present invention can be suitably used for manufacturing a semiconductor device including a step of etching a single crystal silicon film by supplying an etching solution when a silicon wafer, particularly various silicon composite semiconductor devices including a silicon oxide film and/or a silicon nitride film is etched.

A temperature of the silicon etching solution at a time of etching using the silicon etching solution of the present invention may be appropriately determined from a range of 20° ° C. to 95° C. in consideration of a desired etching rate, a shape and a surface state of silicon after etching, productivity, and the like, and is preferably set to a range of 35° C. to 90° C.

At the time of etching using the silicon etching solution of the present invention, it is preferable to perform the etching while performing deaeration or bubbling under vacuum or under a reduced pressure with an inert gas. Such an operation can prevent or reduce an increase in dissolved oxygen during the etching.

At the time of etching using the silicon etching solution of the present invention, an object to be etched may be simply immersed in an etching solution or brought into contact therewith, and an electrochemical etching method of applying a constant potential to the object to be etched can also be used.

Examples of a target object to be etched in the present invention include single crystal silicon, polysilicon, and amorphous silicon containing a silicon oxide film and/or a silicon nitride film, which are non-target objects not to be etched and need to be left in the target object. In addition to the silicon oxide film and the silicon nitride film, various metal films may be included as the non-target objects. Examples thereof include a structure in which a silicon oxide film and a silicon nitride film are alternately stacked on single crystal silicon or a structure in which a silicon oxide film and a polysilicon film are alternately stacked on single crystal silicon, a structure in which a trench is formed in the above stacked structure (stacked film) and a cross section of the stacked film is exposed, and a structure in which a pattern is formed using these films.

### EXAMPLES

Hereinafter, the present invention is described in more detail with reference to Examples, but the present invention is not limited to these Examples.

Experimental methods/evaluation methods in Examples and Comparative Examples are as follows.

(Method for Preparing Etching Solution)

A tetramethylammonium hydroxide (TMAH) aqueous solution (2.73 mol/L) was diluted with ultrapure water and mixed to make a uniform chemical solution, then various additives were added thereto to prepare a composition of each etching solution according to each of Examples and Comparative Examples shown in Table 1, and the etching solution was heated at a temperature during an etching treatment for a predetermined time. At this time, in order to remove dissolved oxygen in the solution, nitrogen bubbling was performed at a supply rate of 0.2 L/min for the last 30 minutes.

(Method for Measuring pH of Etching Solution)

Measurement was performed under a temperature condition of 25° C. using a tabletop pH meter F-73 manufactured by Horiba, Ltd., and a pH electrode 9632-10D for a strong alkaline sample manufactured by Horiba, Ltd.

(pKa of Acid Group-Containing Compound)

Values of the following general documents were referenced. pKa 1 represents an acid dissociation constant of first dissociation, pKa 2 represents an acid dissociation constant of second dissociation, and pKa 3 represents an acid dissociation constant of third dissociation.
Reference Document 1: Everett et al. [Proceedings of the Royal Society of London, Series A: Mathematical, Physical and Engineering Sciences, 1952, vol. 215, p. 403, 409]
Reference Document 2: Edwards, H. G. M.; Smith, D. N. [Journal of Molecular Structure, 1990, vol. 238, #1, p. 27-41]
Reference Document 3: Sari, Hayati; Covington, Arthur K. [Journal of Chemical and Engineering Data, 2005, vol. 50, #5, p. 1620-1623]
Reference Document 4: EP2708533A1

(HLB Value of Acid Group-Containing Compound)

An HLB value was calculated using the following Formula 1 (Davies method). The number of hydrophilic groups used is 19.1 for a Na salt of a carboxy group (—COO⁻Na⁺), and the number of hydrophobic groups used is −0.475 for a methylene group (—CH₂—), a methyl group (—CH₃), and a methine group (═CH—). Since it is considered that an etching solution of this example is alkaline and almost all the carboxy groups are ionized, the value of the Na salt is substituted.

HLB value=7+total value of number of hydrophilic groups+total value of number of lipophilic groups (1)

(Method for Evaluating Silicon Etching Rate (Unit: Nm/Min))

First, the following three types of Si substrates were prepared in order to obtain an etching rate on each crystal plane: the Si (100) plane, the Si (110) plane, and the Si (111) plane.

Substrate A: a 2 cm square single crystal silicon substrate in which front and back surfaces of the substrate are mirror surfaces of the Si (100) plane (manufactured by SUMTEC Service Co., Ltd.)

Substrate B: a 2 cm square single crystal silicon substrate in which front and back surfaces of the substrate are mirror surfaces of the Si (110) plane (manufactured by SUMTEC Service Co., Ltd.)

Substrate C: a 2 cm square single crystal silicon substrate in which front and back surfaces of the substrate are mirror surfaces of the Si (111) plane (manufactured by ENATECH CORPORATION)

Before the etching treatment, weights thereof were separately measured up to five decimal places in unit of “g” using an electronic balance AUW220D manufactured by Shimadzu Corporation.

Each Si substrate was immersed in 100 ml of the etching solution heated to 70° ° C. for 10 minutes to perform the etching treatment. Thereafter, the etched substrate was washed with ultrapure water and then dried.

A weight of each substrate after the above etching treatment was measured in the same manner as before the etching treatment. Using a change in weight before and after etching and 2.329 g/cm³ which is a value of a density of a general single crystal silicon, an etching rate per one surface of the substrate was calculated by the following Formula (2). In the following Formula (2), the unit of the “etching rate” is “nm/min”, the unit of the “areas of front and back surfaces of substrate” is “cm²”, the unit of “2.329” which is a value indicating a density of the single crystal silicon is “g/cm³”, the unit of the “change in weight before and after etching” is “g”, and the unit of the “etching time” is “min”.

Etching rate=areas of front and back surfaces of substrate×10⁷/2.329/change in weight before and after etching/etching time (2)

(Etching Selectivity Ratio Between Si and SiN or SiO₂)

100 mL of a silicon etching solution heated to 70° C. was prepared, and a substrate (a silicon oxide film, manufactured by ENATECH CORPORATION) on which silicon oxide (SiO₂) was epitaxially grown on a silicon substrate having a size of 2 cm×1 cm was immersed therein for 30 minutes. During the etching, the solution was stirred at 1200 rpm, and nitrogen bubbling was continued at 0.2 L/min. The silicon oxide etching rate (RSiO₂) was obtained by measuring a film thickness of each substrate before and after etching with a spectroscopic ellipsometer, obtaining an etching amount of the silicon oxide film from a difference in film thickness before and after the treatment, and dividing the etching amount by the etching time.

Similarly, a silicon nitride etching rate (RSiN) was calculated by immersing, for 30 minutes, a substrate (a silicon nitride film, manufactured by SEIREN KST Corporation) obtained by epitaxially growing silicon nitride on a silicon substrate having a size of 2 cm×1 cm.

An etching selectivity ratio (R′100/RSiO₂) between the Si (100) plane and silicon oxide and an etching selectivity ratio (R′100/RSIN) between the Si (100) plane and silicon nitride were obtained from these measurement results and an etching rate (R′100) of the Si (100) plane measured using a single crystal silicon substrate.

A lower limit of measurement of the change in film thickness by the spectroscopic ellipsometer used is 0.01 nm. Therefore, a lower limit of an etching rate of silicon oxide and silicon nitride which can be determined by the above method is 0.0003 nm/min.

### Reference Example

Using a 0.26 mol/L TMAH aqueous solution, an etching rate of silicon and an etching selectivity ratio between each crystal plane orientation were evaluated. An evaluation result is shown in Table 2.

### Example 1

Using an aqueous solution having a TMAH concentration of 0.26 mol/L, a hydrogen peroxide concentration of 0.07 mol/L, and a hexanoic acid concentration of 0.01 mol/L, the etching rate of silicon and the etching selectivity ratio between each crystal plane orientation were evaluated. The pKa of hexanoic acid is 4.84 (Reference Document 1), and the HLB value of hexanoic acid is 23.7. An evaluation result is shown in Table 2. In this Example, only the etching rate on the Si (110) plane was decreased, and a ratio (R′110/R′111) of the etching rate on the Si (110) plane to an etching rate on the Si (111) plane was improved to 1.9, as compared with Comparative Example 1 which was an experimental example implemented under the same conditions except that hexanoic acid was not added. That is, the crystal plane isotropy in etching was improved. In this composition, R′100/RSiO₂ was 220 and R′100/RSiN was 1100, which were excellent.

### Comparative Example 1

Comparative Example 1 was implemented in the same manner as Example 1 except that hexanoic acid was not added. An evaluation result is shown in Table 2. In this experimental example, the etching rate on the Si (110) plane is higher than that in Example 1, and R′110/R′111 is 2.6, which is higher than a result in Example 1. That is, the crystal plane isotropy in etching is poor.

### Examples 2 and 3

An etching solution in which a TMAH concentration and a hexanoic acid concentration were changed as shown in Table 1 was prepared and evaluated according to contents implemented in Example 1. An evaluation result is shown in Table 2.

In these experimental examples, although the etching rate on the Si (111) plane was slightly decreased as compared with Comparative Example 1, the etching rate on the Si (110) plane was relatively largely decreased, and as a result, R′110/R′111 was improved as compared with Comparative Example 1.

### Examples 4 and 5

An etching solution containing an additive shown in Table 1 instead of hexanoic acid was prepared and evaluated according to the contents implemented in Example 1. Concentrations are shown in Table 1, and an evaluation result is shown in Table 2.

### Example 6

An etching solution containing phthalic acid instead of hexanoic acid was prepared and evaluated according to the contents implemented in Example 1. Phthalic acid has two carboxy groups, the pKa 1 thereof is 3.1, and the pKa 2 thereof is 5.08 (Reference Document 3). The HLB value thereof is 42.4. Concentrations are shown in Table 1, and an evaluation result is shown in Table 2.

### Example 7

An etching solution containing phosphoric acid instead of hexanoic acid was prepared and evaluated according to the contents implemented in Example 1. The pKa 1 of phosphoric acid is 2.12, the pKa 2 thereof is 7.2, and the pKa 3 thereof is 12.36 (Reference Document 4). Concentrations are shown in Table 1, and an evaluation result is shown in Table 2.

### Comparative Examples 2 and 3

An etching solution containing an additive shown in Table 1 (ethanesulfonic acid (pKa: −1.7 (Reference Document 2) or sodium octanesulfonate)) instead of hexanoic acid was prepared and evaluated according to the contents implemented in Example 1. Concentrations and an evaluation result are shown in Table 2. In these experimental examples, the etching rate on Si (110) hardly decreased, and R′110/R′111 did not improve much as compared with Comparative Example 1. Since the sulfonic acid group has low pKa, there is almost no acid group in a free state, and it is considered that adsorption to a silicon surface is difficult to occur.

### Example 8

A hexanoic acid concentration was changed as shown in Table 1, and an oxidizing agent was changed to meta-chloroperoxybenzoic acid instead of hydrogen peroxide to prepare an etching solution having the contents implemented in Example 1. Concentrations are shown in Table 1, and an evaluation result is shown in Table 2.

### Comparative Example 4

Comparative Example 4 was implemented in the same manner as Example 8 except that hexanoic acid was not added. In this experimental example, the etching rate on the Si (110) plane is higher than that in Example 8, and R′110/R′111 is 3.1, which is higher than the result in Example 8. That is, the crystal plane isotropy in etching is poor.

### Comparative Example 5

Comparative Example 5 was implemented in the same manner as Comparative Example 1 except that a hydrogen peroxide concentration was changed as shown in Table 1. An evaluation result is shown in Table 2. In this experimental example, the etching rate on the Si (100) plane was significantly decreased compared with Comparative Example 1, and R′100/R′111 was 0.3, which was worse than the result in Comparative Example 1. That is, the crystal plane isotropy in etching is poor.

TABLE 1

| | Etching solution composition | | | | | | | | | | | |
|---|---|---|---|---|---|---|---|---|---|---|---|---|
| | Quaternary | | | | | | | | | | | |
| | ammonium | | | | Acid group-containing compound | | | | | | | |
| | hydroxide | | Oxidizing agent | | | | Davies | | | | Etching | |
| | | Concen- | | Concen- | | Concen- | method | | | | temper- | Etching |
| | | tration | | tration | | tration | HLB | pKa (at 25° C.) | | | ature | solution |
| | Type | (mol/L) | Type | (mol/L) | Type | (mol/L) | value | pKa1 | pKa2 | pKa3 | (° C.) | pH |
| Reference | TMAH | 0.26 | Not added | N.D. | Not added | N.D. | N.D. | N.D. | N.D. | N.D. | 70 | 13.4 |
| Example | | | | | | | | | | | | |
| Example 1 | TMAH | 0.26 | Hydrogen | 0.07 | Hexanoic | 0.01 | 23.7 | 4.84 | N.D. | N.D. | 70 | 13.3 |
| | | | peroxide | | acid | | | | | | | |
| Example 2 | TMAH | 0.21 | Hydrogen | 0.04 | Hexanoic | 0.01 | 23.7 | 4.84 | N.D. | N.D. | 70 | 12.8 |
| | | | peroxide | | acid | | | | | | | |
| Example 3 | TMAH | 0.26 | Hydrogen | 0.07 | Hexanoic | 0.04 | 23.7 | 4.84 | N.D. | N.D. | 70 | 13.3 |
| | | | peroxide | | acid | | | | | | | |
| Example 4 | TMAH | 0.26 | Hydrogen | 0.07 | Butanoic | 0.01 | 24.7 | 4.83 | N.D. | N.D. | 70 | 13.4 |
| | | | peroxide | | acid | | | | | | | |
| Example 5 | TMAH | 0.26 | Hydrogen | 0.07 | Octanoic | 0.07 | 22.8 | 4.90 | N.D. | N.D. | 70 | N.D. |
| | | | peroxide | | acid | | | | | | | |
| Example 6 | TMAH | 0.26 | Hydrogen | 0.07 | Phthalic | 0.01 | 42.4 | 3.1 | 5.08 | N.D. | 70 | N.D. |
| | | | peroxide | | acid | | | | | | | |
| Example 7 | TMAH | 0.26 | Hydrogen | 0.07 | Phosphoric | 0.01 | N.D. | 2.12 | 7.2 | 12.36 | 70 | N.D. |
| | | | peroxide | | acid | | | | | | | |
| Example 8 | TMAH | 0.26 | Meta- | 0.06 | Hexanoic | 0.09 | 23.7 | 4.84 | N.D. | N.D. | 70 | N.D. |
| | | | chloroperoxy- | | acid | | | | | | | |
| | | | benzoic acid | | | | | | | | | |
| Comparative | TMAH | 0.26 | Hydrogen | 0.07 | Not added | N.D. | N.D. | N.D. | N.D. | N.D. | 70 | 13.2 |
| Example 1 | | | peroxide | | | | | | | | | |
| Comparative | TMAH | 0.26 | Hydrogen | 0.07 | Ethane- | 0.01 | N.D. | −1.7 | N.D. | N.D. | 70 | N.D. |
| Example 2 | | | peroxide | | sulfonic | | | | | | | |
| | | | | | acid | | | | | | | |
| Comparative | TMAH | 0.26 | Hydrogen | 0.07 | Sodium | 0.005 | N.D. | N.D. | N.D. | N.D. | 70 | N.D. |
| Example 3 | | | peroxide | | octane- | | | | | | | |
| | | | | | sulfonate | | | | | | | |
| Comparative | TMAH | 0.26 | Meta- | 0.06 | Not added | N.D. | N.D. | N.D. | N.D. | N.D. | 70 | 13.3 |
| Example 4 | | | chloroperoxy- | | | | | | | | | |
| | | | benzoic acid | | | | | | | | | |
| Comparative | TMAH | 0.26 | Hydrogen | 0.10 | Not added | N.D. | N.D. | N.D. | N.D. | N.D. | 70 | N.D. |
| Example 5 | | | peroxide | | | | | | | | | |

N.D.: not detected

TABLE 2

| | | | | | | Etching selectivity | | | |
|---|---|---|---|---|---|---|---|---|---|
| | Etching rate (nm/min) | | | | | Si(100)/ | Si(110)/ | Si(100)/ | Si(100)/ |
| | Si(100) | Si(110) | Si(111) | SiO₂ | SiN | Si(111) | Si(111) | SiO₂ | SiN |
| Reference | 335 | 370 | 86 | 0.07 | 0.01 | 3.9 | 4.3 | 4786 | 33500 |
| Example | | | | | | | | | |
| Example 1 | 13 | 24 | 13 | N.D | N.D. | 1.0 | 1.9 | N.D. | N.D. |
| Example 2 | 11 | 21 | 12 | 0.05 | 0.01 | 0.9 | 1.7 | 220 | 1100 |
| Example 3 | 8 | 18 | 9 | N.D. | N.D. | 0.9 | 1.9 | N.D. | N.D. |
| Example 4 | 10 | 24 | 11 | N.D. | N.D. | 0.9 | 2.2 | N.D. | N.D. |
| Example 5 | 6 | 9 | 6 | N.D. | N.D. | 1.0 | 1.5 | N.D. | N.D. |
| Example 6 | 13 | 28 | 14 | N.D. | N.D. | 1.0 | 2.1 | N.D. | N.D. |
| Example 7 | 11 | 23 | 12 | N.D. | N.D. | 0.9 | 1.9 | N.D. | N.D. |
| Example 8 | 3 | 4 | 4 | N.D. | N.D. | 0.8 | 1.0 | N.D. | N.D. |
| Comparative | 14 | 34 | 13 | 0.05 | 0.01 | 1.1 | 2.6 | 280 | 1400 |
| Example 1 | | | | | | | | | |
| Comparative | 15 | 31 | 13 | N.D. | N.D. | 1.2 | 2.4 | N.D. | N.D. |
| Example 2 | | | | | | | | | |
| Comparative | 17 | 31 | 13 | N.D. | N.D. | 1.3 | 2.4 | N.D. | N.D. |
| Example 3 | | | | | | | | | |
| Comparative | 17 | 37 | 12 | N.D. | N.D. | 1.4 | 3.1 | N.D. | N.D. |
| Example 4 | | | | | | | | | |
| Comparative | 2 | 9 | 6 | N.D. | N.D. | 0.3 | 1.5 | N.D. | N.D. |
| Example 5 | | | | | | | | | |

N.D.: not detected

What is claimed is:

1. A silicon etching solution comprising:
a quaternary ammonium hydroxide;
an oxidizing agent;
water; and
an acid group-containing compound having at least one acid group selected from the group consisting of a carboxy group, a sulfonic acid group, a phosphoric acid group, and a phosphonic acid group, and having at least one pKa of 3.5 or more and 13 or less.

2. The silicon etching solution according to claim 1, wherein the acid group-containing compound has only one acid group.

3. The silicon etching solution according to claim 2, wherein the acid group-containing compound has a carboxy group and has an HLB value of 23.0 or more and 25.5 or less.

4. The silicon etching solution according to claim 3, wherein a content of the acid group-containing compound is 0.001 mol/L or more and 0.1 mol/L or less.

5. The silicon etching solution according to claim 1, wherein the acid group-containing compound is one or more compounds selected from the group consisting of propanoic acid, butanoic acid, pentanoic acid, hexanoic acid, heptanoic acid, octanoic acid, isopropanoic acid, isobutanoic acid, isopentanoic acid, isohexanoic acid, isoheptanoic acid, isooctanoic acid, 2-cyclobutylacetic acid, cyclopentanecarboxylic acid, cyclohexanecarboxylic acid, succinic acid, glutaric acid, adipic acid, pimelic acid, suberic acid, azelaic acid, sebacic acid, tridecanedioic acid, methylsuccinic acid, tetramethylsuccinic acid, benzoic acid, terephthalic acid, gluconic acid, phosphoric acid, ethylphosphonic acid, propylphosphonic acid, butylphosphonic acid, pentylphosphonic acid, heptylphosphonic acid, octylphosphonic acid, isopropylphosphonic acid, isobutylphosphonic acid, isopentylphosphonic acid, isoheptylphosphonic acid, isooctylphosphonic acid, and salts thereof.

6. The silicon etching solution according to claim 1, wherein the oxidizing agent is one or more selected from the group consisting of hydrogen peroxide, meta-chloroperoxybenzoic acid, and an N-oxyl compound.

7. A method for treating a substrate, comprising:
a step of bringing the silicon etching solution according claim 1 into contact with a substrate having a Si plane to etch the Si plane.

8. A method for manufacturing a silicon device, comprising
the method for treating a substrate according to claim 7 during manufacturing a silicon device.
